(19) United States
(12) Patent Application Publication
(10) Pub. No.: US 2011/0049708 A1
(43) Pub. Date: Mar. 3, 2011

(54) Semiconductor Chip Interconnection Structure and Semiconductor Package Formed Using the Same

(75) Inventors: Lim Shoa Siong, Singapore (SG); Lim Kian Hock, Singapore (SG); Chew Hwee-Seng Jimmy, Singapore (SG)

(73) Assignee: ADVANPACK SOLUTIONS PTE LTD.

(21) Appl. No.: 12/870,216

(22) Filed: Aug. 27, 2010

Related U.S. Application Data
(60) Provisional application No. 61/237,370, filed on Aug. 27, 2009.

(30) Foreign Application Priority Data
Aug. 23, 2010 (TW) 99128133
Aug. 27, 2010 (CN) 101020507572.6
Aug. 27, 2010 (CN) 201010264703.3

(51) Int. Cl. H01L 23/58

(52) U.S. Cl. 257/737; 257/E23.002

(57) ABSTRACT

A semiconductor chip interconnection structure and a semiconductor package formed using the same are provided. The semiconductor chip interconnection structure comprises a chip, a bump assembly and an electrical element. The chip comprises a pad and has a pad aperture from which the pad is exposed. The bump assembly comprises a first bump and a second bump. The first bump is disposed on the pad. The second bump is disposed on the first bump. The outer diameter of the second bump is not less than the outer diameter of the first bump. The electrical element is connected to the bump assembly.

This application claims the benefit of U.S. provisional application Ser. No. 61/237,370, filed Aug. 27, 2009, the subject matter of which is incorporated herein by reference.

### BACKGROUND OF THE INVENTION

1. Field of the Invention

The invention relates in general to a semiconductor chip interconnection structure and a semiconductor package formed using the same, and more particularly to a semiconductor chip interconnection structure with stacked bumps and a semiconductor package formed using the same.

2. Description of the Related Art

Referring to FIG. 1 (prior art), a generally known semiconductor chip interconnection structure is shown. The semiconductor chip interconnection structure 10 comprises a substrate 12, a pad 14, a bump 16 and a solder layer 18.

However, during reflow process, the solder layer 18 disposed on bump 16 often flows to the pad 14 and spoils the pad 14, largely affecting the electrical properties and reliability of the pad 14.

### SUMMARY OF THE INVENTION

The invention is directed to a semiconductor chip interconnection structure and a semiconductor package formed using the same. The electrical element, having been reflown, does not contact the pad so that the electrical properties and reliability of the pad will not be affected.

According to a first aspect of the present invention, a semiconductor chip interconnection structure is provided. The semiconductor chip interconnection structure comprises a chip, a bump assembly and an electrical element. The chip comprises a pad and has a pad aperture from which the pad is exposed. The bump assembly comprises a first bump and a second bump. The first bump is disposed on the pad. The second bump is disposed on the first bump. The outer diameter of the second bump is not less than the outer diameter of the first bump. The electrical element is connected to the bump assembly.

According to a second aspect of the present invention, a semiconductor package is provided. The semiconductor package comprises a substrate and a semiconductor chip interconnection structure. The semiconductor chip interconnection structure comprises a chip, a bump assembly and an electrical element. The chip comprises a pad and has a pad aperture from which the pad is exposed. The bump assembly comprises a first bump and a second bump. The first bump is disposed on the pad. The second bump is disposed on the first bump. The outer diameter of the second bump is not less than the outer diameter of the first bump. The electrical element is connected to the bump assembly.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 (prior art) shows a generally known semiconductor chip interconnection structure;

FIG. 2 shows a semiconductor chip interconnection structure according to a first embodiment of the invention;

FIG. 3 shows the semiconductor chip interconnection structure of FIG. 2;

FIG. 4 shows a semiconductor chip interconnection structure according to a second embodiment of the invention;

FIG. 5 shows a semiconductor chip interconnection structure according to a third embodiment of the invention;

FIG. 6 shows a semiconductor chip interconnection structure according to a fourth embodiment of the invention;

FIG. 7 shows a semiconductor chip interconnection structure according to a fifth embodiment of the invention;

FIG. 8 shows a semiconductor chip interconnection structure according to a sixth embodiment of the invention; and

FIG. 9 shows a semiconductor chip interconnection structure according to a seventh embodiment of the invention.

### DETAILED DESCRIPTION OF THE INVENTION

### First Embodiment

Referring to FIG. 2, a semiconductor chip interconnection structure according to a first embodiment of the invention is shown. The semiconductor package 100 comprises a substrate 110, a semiconductor chip interconnection structure 112 and an underfill 132. The underfill 132 is disposed between the substrate 110 and the semiconductor chip interconnection structure 112.

The semiconductor chip interconnection structure 112, such as a flip chip, a lead frame or a substrate, is electrically connected to the substrate 110 through the electrical element 108 such as solder ball or solder layer.

Referring to FIG. 3, the semiconductor chip interconnection structure of FIG. 2 is shown. The semiconductor chip interconnection structure illustrated in FIG. 3 is not connected to the substrate 110. The semiconductor chip interconnection structure 112 comprises a chip 126, a bump assembly 118, an electrical element 108 and a pad 114.

The chip 126 comprises a pad 114 and has a pad aperture 116 from which the pad 114 is exposed. The electrical element 108 is connected to the bump assembly 118.

The bump assembly 118 comprises a first bump 120 and a second bump 122. The first bump 120 is disposed on the pad 114. The second bump 122 is disposed on the first bump 120. The outer diameter D12 of the second bump 122 is larger than the outer diameter D11 of the first bump 120. The “outer diameter” refers to the radial size of a bump measured from the outside, while the “inner diameter” refers to the radial size of an aperture measured from the inside.

Preferably but not restrictively, the bump assembly 118 is made from silver or copper by thermosonic wirebonding. Preferably but not restrictively, the first bump 120 is formed by silver and the second bump 122 is formed by copper. Preferably but not restrictively, the pad 114 is an aluminum pad. Preferably but not restrictively, the electrical element 108 is formed by a material selected from a group consisting of tin, silver, copper and lead.

The outer diameter D12 of the second bump 122 is larger than the outer diameter D11 of the first bump 120 and the inner diameter DP of the pad aperture 116. That is, the second bump 122 can completely shield the upper surface of the first bump 120 and the pad aperture 116. Since the outer diameter D12 of the second bump 122 is larger than the inner diameter DP of the pad aperture 116, the electrical element 108, having been reflown, can be completely formed on the second bump 122 (as indicated in FIG. 3) and will not overflow to the pad 114 to spoil the pad 114.

Further, by suitable design of the outer diameter D12 of the second bump 122, the upper surface 134 of the second bump 122 can be large enough so that the electrical element 108, having been reflown, can be completely formed on the second bump 122. Thus, the problem of overflowing is avoided.

Since the electrical element 108, having been reflown, can be completely formed on the second bump 122, the electrical element 108 can thus be controlled in the manufacturing process. Thus, the height, the size and the shape of the electrical element 108 can be controlled according to the needs in the manufacturing process, so that the manufacturing process is more flexible.

The size of second bump 122 is independent of the size of the pad 114. Thus, the second bump 122 can be designed to have a larger size for bearing larger electrical element 108, so that the bonding and electrical properties between the electrical element 108 and the counterpart member are enhanced.

In addition, the first bump 120 and the second bump 122 booster the substrate 110 and increase the distance between the substrate 110 and the pad 114 so as to facilitate the formation of the underfill 132 and increase the reliability of the semiconductor package 100.

The first bump 120 and the second bump 122 can be formed by different materials. For example, the first bump 120 is formed by softer and more expensive gold (Au) and is formed on the pad 114, and the second bump 122 is formed by harder and cheaper copper (Cu), so as to reduce the packaging costs and avoid the chip 126 being damaged during the formation of the first bump 120.

### Second Embodiment

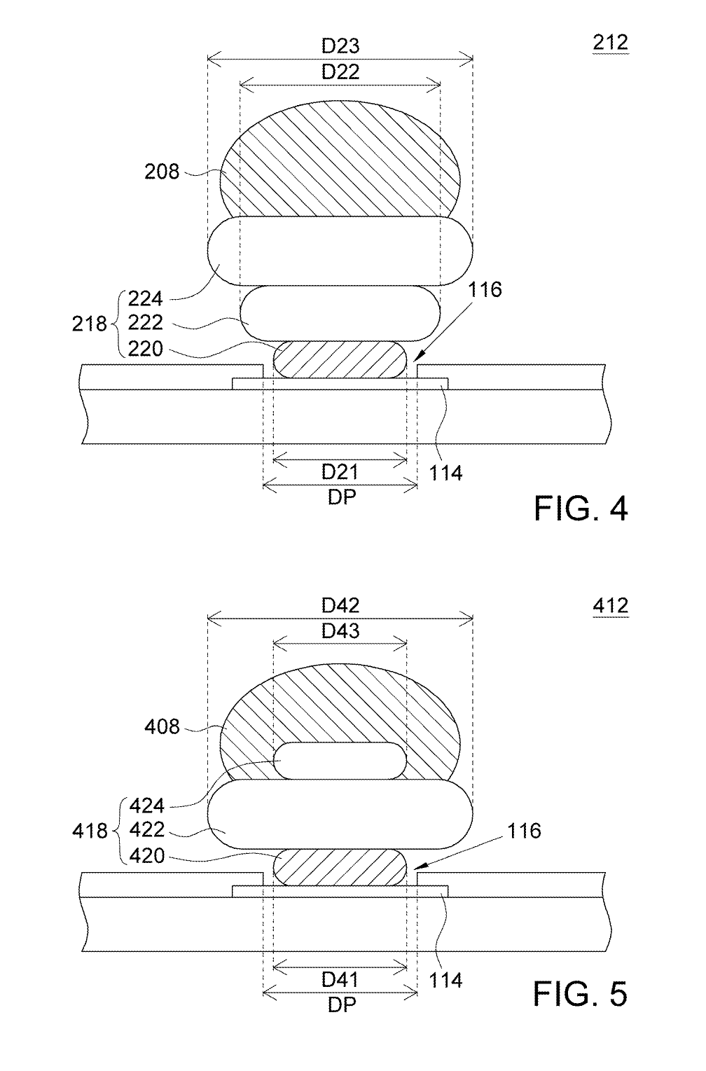

Referring to FIG. 4, a semiconductor chip interconnection structure according to a second embodiment of the invention is shown. In the second embodiment, the elements similar to the first embodiment use the same designations and are not repeated here. The semiconductor chip interconnection structure 212 of the second embodiment is different from the semiconductor chip interconnection structure 112 of the first embodiment in that the bump assembly 218 of the semiconductor chip interconnection structure 212 further comprises a third bump 224. Preferably but not restrictively, the third bump 224 is formed by copper.

The bump assembly 218 comprises a first bump 220, a second bump 222 and a third bump 224. The outer diameter D23 of the third bump 224 is larger than the outer diameter D22 of the second bump 222, the outer diameter D21 of the first bump 220, and the inner diameter DP of the pad aperture 116. The outer diameter D22 of the second bump 222 is larger than the outer diameter D21 of the first bump 220. That is, the third bump 224 can completely shield the upper surface of the second bump 222, the upper surface of the first bump 220, and the pad aperture 116.

Since the outer diameter D23 of the third bump 224 is larger than the inner diameter DP of the pad aperture 116, the electrical element 208, having been reflown, can be completely formed on the third bump 224 as indicated in FIG. 4, and will not spoil the pad 114.

### Third Embodiment

Referring to FIG. 5, a semiconductor chip interconnection structure according to a third embodiment of the invention is shown. In the third embodiment, the elements similar to the second embodiment use the same designations and are not repeated here. The semiconductor chip interconnection structure 412 of the third embodiment is different from the semiconductor chip interconnection structure 212 of the second embodiment in that the outer diameter D43 of the third bump 424 of the bump assembly 418 of the semiconductor chip interconnection structure 412 is smaller than the second bump 422 the outer diameter of D42.

The bump assembly 418 comprises a first bump 420, a second bump 422 and a third bump 424. The outer diameter D43 of the third bump 424 is smaller than the outer diameter D42 of the second bump 422. The outer diameter D42 of the second bump 422 is larger than the outer diameter D41 of the first bump 420 and the inner diameter DP of the pad aperture 116. That is, the second bump 422 can completely shield the upper surface of the first bump 420 and the pad aperture 116.

The third bump 424 enhances the bonding between the electrical element 408 and the second bump 422. During the reflowing process, the third bump 424 blocks the flowing electrical element 408. Since the third bump 424 changes the surface silhouette of the second bump 422, the third bump 424 avoids the electrical element 408 overflowing to the pad 114.

### Fourth Embodiment

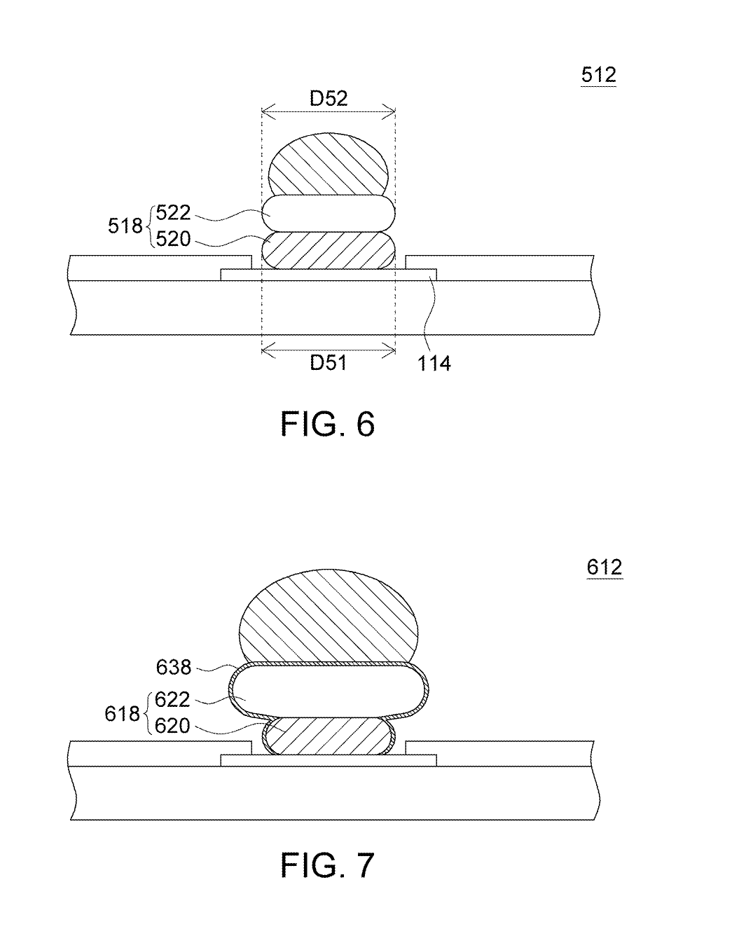

Referring to FIG. 6, a semiconductor chip interconnection structure according to a fourth embodiment of the invention. In the fourth embodiment, the elements similar to the first embodiment use the same designations and are not repeated here. The semiconductor chip interconnection structure 512 of the fourth embodiment is different from the semiconductor chip interconnection structure 112 of the first embodiment in that, the outer diameter D52 of the second bump 522 of the bump assembly 518 of the semiconductor chip interconnection structure 512 is substantially equal to the outer diameter D51 of the first bump 520.

In addition, the first bump 520 and the second bump 522 stacked together booster the substrate 110, facilitate the formation of the underfill 132 and further increase the reliability of the semiconductor package 100. Moreover, the first bump 520 and the second bump 522 can be formed by different materials. For example, the first bump 520 is formed by softer and more expensive gold (Au) and is formed on the pad 114, and the second bump 522 is formed by harder and cheaper copper (Cu), so as to reduce the packaging costs and avoid the chip 126 being damaged during the formation of the first bump 120.

### Fifth Embodiment

Referring to FIG. 7, a semiconductor chip interconnection structure according to a fifth embodiment of the invention is shown. In the fifth embodiment, the elements similar to the first embodiment use the same designations and are not repeated here. The semiconductor chip interconnection structure 612 of the fifth embodiment is different from the semiconductor chip interconnection structure 112 of the first embodiment in that the bump assembly 618 of the semiconductor chip interconnection structure 612 further comprises a coating layer 638 which covers on the outer surface of the first bump 620 and the outer surface of the second bump 622. Preferably but not restrictively, the coating layer 638 covers the entirety of the first bump 620 and the second bump 622. The coating layer 638 can protect the first bump 620 and the second bump 622 from environmental erosion such as oxidization.

In the present embodiment of the invention, after the first bump 620 and the second bump 622 are formed, the coating layer 638 can be formed by sputtering technology or the electroless plating technology. In another implementation, the solder wire (not illustrated) used for forming the first bump 620 and the second bump 622 has a coating layer 638. After the wire bonding head forms the first bump 620 and the second bump 622 on the substrate, the coating layer 638 is still on the first bump 620 and the second bump 622.

Preferably but not restrictively, the coating layer 638 is formed by at least one of nickel (Ni) and gold (Au), and can be realized by such as nickel-gold alloy, chemical nickel gold (ENIG) or gold.

In the fifth embodiment, the coating layer 638 covers the first bump 620 and the second bump 622 of FIG. 7. However, anyone who is skilled in the technology of the invention will understand that the coating layer 638 can also be formed on the first, the second and the third bumps of the second and the third embodiments as well as the first and the second bumps of the fourth embodiment.

### Sixth Embodiment

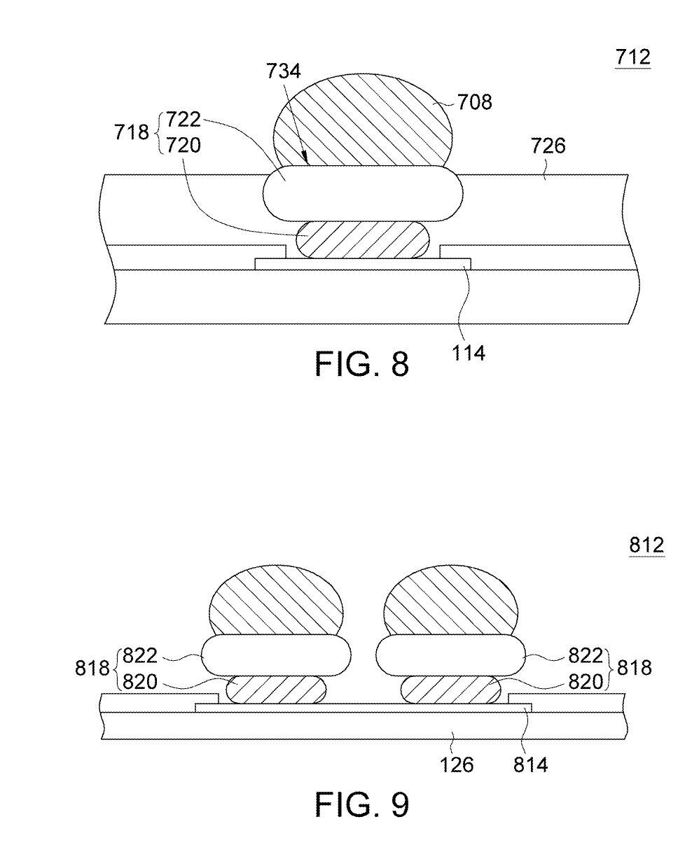

Referring to FIG. 8, a semiconductor chip interconnection structure according to a sixth embodiment of the invention is shown. In the sixth embodiment, the elements similar to the first embodiment use the same designations and are not repeated here. The semiconductor chip interconnection structure 712 of the sixth embodiment is different from the semiconductor chip interconnection structure 112 of the first embodiment in that the semiconductor chip interconnection structure 712 further comprises an insulating layer 726, which covers the bump assembly 718, and the upper surface 734 of second bump 722 is not covered by the insulating layer 726 and is exposed for electrically connecting the electrical element 708.

The second bump 722 is disposed on the first bump 720, and the electrical element 708 is disposed on the second bump 722.

The insulating layer 726 protects the bump assembly 718 from environmental erosion such as oxidization. The insulating layer 726 completely avoids the electrical element 708 overflowing to the pad 114, so that the electrical properties and reliability between the bump assembly 718 and the pad 114 are enhanced

In the sixth embodiment, the insulating layer 726 is formed on the semiconductor chip interconnection structure 712 of FIG. 8. However, anyone who is skilled in the technology of the invention will understand that the insulating layer 726 can also be formed on the bump assemblies of the second to the fifth embodiments.

When the insulating layer 726 is formed on the bump assembly of the second embodiment (FIG. 4) to the third embodiment (FIG. 5), the insulating layer 726 covers a lateral side of the bump assembly but not the surface of the bump of the bump assembly connected to the electrical element, so that the surface of the bump can be exposed for electrically connecting the electrical element. In the example of FIG. 3 (the first embodiment), the insulating layer covers the bump assembly 118 and exposes the upper surface 134 of the second bump 122. In the example of FIG. 4 (the second embodiment), the insulating layer covers the bump assembly 218 and exposes the upper surface of the third bump 224. In the example of FIG. 5 (the third embodiment), the insulating layer covers the bump assembly 418 and exposes the upper surfaces of the second bump 422 and the third bump 424.

In another implementation (not illustrated), the bump assembly of the semiconductor chip interconnection structure 712 can form a coating layer 638 of the fifth embodiment.

### Seventh Embodiment

Referring to FIG. 9, a semiconductor chip interconnection structure according to a seventh embodiment of the invention is shown. In the seventh embodiment, the elements similar to the first embodiment use the same designations and are not repeated here. The semiconductor chip interconnection structure 812 of the seventh embodiment is different from the semiconductor chip interconnection structure 112 of the first embodiment in that the semiconductor chip interconnection structure 812 comprises two bump assemblies 818, which are concurrently formed on a single pad 814.

Each bump assembly 818 comprises a first bump 820 and a second bump 822. The two bump assemblies 818 are both formed on the pad 814.

If smaller first bumps 820 are used, two sets of first bumps 820 can be formed on the pad 814, so that the number of I/O contacts can be further increased.

In another implementation (not illustrated), the insulating layer 726 of the sixth embodiment can be formed on the semiconductor chip interconnection structure 812 to protect the bump assembly 818. Preferably but not restrictively, a portion (not illustrated) of the insulating layer 726 can be disposed between two bump assemblies 818.

In another implementation (not illustrated), the coating layer 638 of the fifth embodiment can be formed on the bump assembly of the semiconductor chip interconnection structure 812.

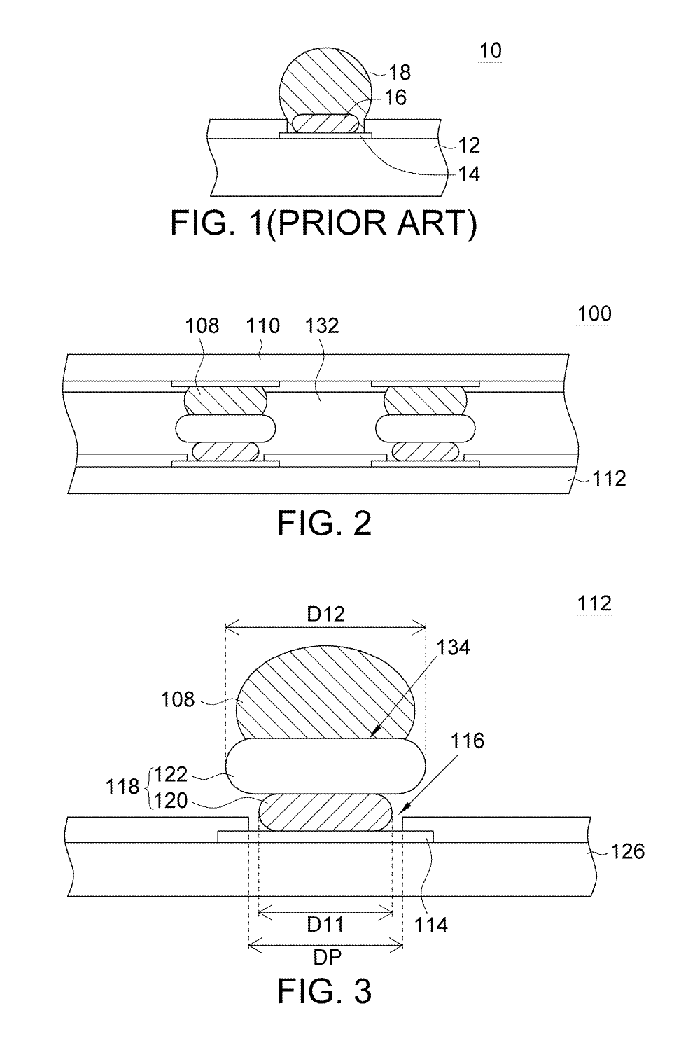

Further, the above semiconductor chip interconnection structures 212, 312, 412, 512, 612, 712 and 812 can be electrically connected to the substrate 110 of FIG. 1, and the bonded semiconductor package being similar to the semiconductor package 100 of the first embodiment is not repeated here.

According to the semiconductor chip interconnection structure and the semiconductor package disclosed in the above embodiments of the invention, the outer diameter of the bump contacting the electrical element is suitably designed, so that the surface of the bump contacting the electrical element is large enough. Thus, the electrical element, having been reflown, can be completely formed on the bump, and will not overflow to the pad to spoil the pad. The electrical element, having been flown, can be completely formed on the bump, so that the electrical element is more controllable in the manufacturing process. Thus, the height, the size and the shape of the electrical element 108 can be controlled according to the needs in the manufacturing process, so that the manufacturing process is more flexible. Moreover, the size of bump contacting the electrical element is independent of the size of the pad. Thus, the bump can be designed to have a larger size for bearing larger electrical element, so that the bonding and electrical properties between the electrical element and the counterpart member are enhanced.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor chip interconnection structure, comprising:
a chip comprising a pad and having a pad aperture from which the pad is exposed;
a bump assembly, comprising:
a first bump disposed on the pad; and
a second bump disposed on the first bump, wherein the outer diameter of the second bump is not less than the outer diameter of the first bump; and
an electrical element connected to the bump assembly.

2. The semiconductor chip interconnection structure according to claim 1, further comprising:
an insulating layer encapsulating the bump assembly, wherein the upper surface of the second bump is exposed.

3. The semiconductor chip interconnection structure according to claim 1, wherein the outer diameter of the second bump is not less than the inner diameter of the pad aperture.

4. The semiconductor chip interconnection structure according to claim 3, wherein the bump assembly further comprises:
a third bump disposed on the second bump;
wherein, the outer diameter of the third bump is smaller than the outer diameter of the second bump.

5. The semiconductor chip interconnection structure according to claim 1, wherein the bump assembly further comprises:
a third bump disposed on the second bump;
wherein, the outer diameter of the third bump is not less than the outer diameter of the second bump.

6. The semiconductor chip interconnection structure according to claim 1, wherein the bump assembly further comprises:
a coating layer covering on the first bump and the second bump.

7. The semiconductor chip interconnection structure according to claim 6, wherein the coating layer is made of a material selected from a group consisting of nickel (Ni) and gold (Au).

8. The semiconductor chip interconnection structure according to claim 1, wherein the bump assembly further comprises a third bump disposed on the second bump, and the semiconductor chip interconnection structure further comprises:
an insulating layer encapsulating the bump assembly, wherein the upper surface of the third bump is exposed.

9. A semiconductor package comprising:
a substrate; and
a semiconductor chip interconnection structure comprising:
a chip comprising a pad and having a pad aperture from which the pad is exposed;
a bump assembly comprising:
a first bump disposed on the pad; and
a second bump disposed on the first bump, wherein the outer diameter of the second bump is not less than the outer diameter of the first bump; and
an electrical element connected to the bump assembly.

10. The semiconductor package according to claim 9, wherein the semiconductor chip interconnection structure further comprises:
an insulating layer encapsulating the bump assembly, wherein the upper surface of the second bump is exposed.

11. The semiconductor package according to claim 9, wherein the outer diameter of the second bump is not less than the inner diameter of the pad aperture.

12. The semiconductor package according to claim 11, wherein the bump assembly further comprises:
a third bump disposed on the second bump;
wherein, the outer diameter of the third bump is smaller than the outer diameter of the second bump.

13. The semiconductor package according to claim 9, wherein the bump assembly further comprises:
a third bump disposed on the second bump;
wherein, the outer diameter of the third bump is not less than the outer diameter of the second bump.

14. The semiconductor package according to claim 9, wherein the bump assembly further comprises:
a coating layer covering the first bump and the second bump.

15. The semiconductor package according to claim 14, wherein the coating layer is made of a material selected from a group consisting of nickel and gold.

16. The semiconductor package according to claim 9, wherein the bump assembly further comprises a third bump disposed on the second bump, and the semiconductor chip interconnection structure further comprises:
an insulating layer encapsulating the bump assembly, wherein the upper surface of the third bump is exposed.
